(19) United States
(12) Patent Application Publication
(10) Pub. No.: US 2024/0282484 A1
(43) Pub. Date: Aug. 22, 2024

(54) COMMUNICATION CABLE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Shuhei OZU, Osaka (JP); Hiroyuki KODAMA, Osaka (JP); Tatsuya SHIMADA, Mie (JP); Hiroyuki KOBAYASHI, Mie (JP); Yuta YASUYOSHI, Mie (JP)

(21) Appl. No.: 18/568,972

(22) PCT Filed: Jun. 6, 2022
(86) PCT No.: PCT/JP2022/022735

§ 371 Date: Dec. 11, 2023

(30) Foreign Application Priority Data
Jun. 25, 2021 (JP) 2021-105379

(51) Int. Cl. H01B 11/10; H01B 11/18

(52) U.S. Cl. CPC H01B 11/1033; H01B 11/18

(57) ABSTRACT

A communication cable 1 includes: a core wire 2 having a conductor 21 and an insulating layer 22 covering an outer circumference of the conductor 21; and a film-like shield 3 that longitudinally surrounds an outer circumference of the core wire 2, in which the film-like shield 3 includes a metal base layer 32 constituted by a metal layer, and a linear or band-shaped stripe member 33 that is in intimate contact with the metal base layer 32, and a plurality of the stripe members 33 extend in an axial direction A1 of the core wire 2 and are spaced apart from each other in a circumferential direction A2 of the core wire.

### TECHNICAL FIELD

The present disclosure relates to a communication cable.

### BACKGROUND

In communication cables used in the fields of automobiles and the like, there are cases where a shield body provided with a metal layer made of copper, aluminum, or an alloy containing copper or aluminum is disposed on an outer circumference of a core wire as a noise shielding layer for suppressing the entry of noise from the outside and the emission of noise to the outside. Patent Document 1 discloses a communication cable provided with a metal foil shield, for example.

### PRIOR ART DOCUMENT

### Patent Document

Patent Document 1: JP 2009-146850 A
Patent Document 2: JP H03-112828 U
Patent Document 3: JP 2002-329425 A
Patent Document 4: JP S63-146913 U
Patent Document 5: JP H05-090739 U

### SUMMARY OF THE INVENTION

### Problems to be Solved

It is easier to obtain high shielding performance for a communication cable by disposing a film-like shield having a metal layer in a longitudinal arrangement rather than in a laterally wound arrangement. However, when a longitudinally arranged film shield is used, a crack may be formed in the metal layer of the film-like shield when the communication cable is repeatedly bent. Because bending involves bending of a communication cable in its axial direction, a crack is likely to form in a metal layer of the film-like shield, in a direction that intersects the axial direction, i.e., a direction surrounding the axial direction, or a direction close thereto. If a crack is formed in the metal layer of the film-like shield, shielding performance may deteriorate, and sufficient noise shielding may not be possible.

In particular, in the field of automobiles, following the development of self-driving technology, there is a need for communication cables capable of transmitting a large amount of information at high speed, such as information necessary for recognizing images of the outside of vehicles. This increase in the communication speed makes the influence of noise more critical. Therefore, it is desirable to provide communication cables with high shielding performance. Thus, it is preferable to suppress the formation of a crack in a film-like shield due to bending as described above. However, as a result of bending, wires routed in areas where the wires are repeatedly bent, such as inside automobile doors, are located in an environment where, a crack extending in a direction that intersects the axial direction of a communication cable is likely to form in a film-like shield.

In view of the above-described issues, the present disclosure aims to provide a communication cable in which the formation of a crack, which will result in the deterioration of shielding performance, in a film-like noise shielding member having a metal layer, is suppressed.

### Means to Solve the Problem

A communication cable according to this disclosure includes: a core wire having a conductor and an insulating layer covering an outer circumference of the conductor; and a film-like shield that longitudinally surrounds an outer circumference of the core wire, in which the film-like shield includes a metal base layer constituted by a metal layer, and a linear or band-shaped stripe member that is in intimate contact with the metal base layer, and a plurality of the stripe members extend in an axial direction of the core wire and are spaced apart from each other in a circumferential direction of the core wire.

### Effect of the Invention

The communication cable according to the present disclosure is a communication cable in which the formation of a crack, which will result in the deterioration of shielding performance, in a film-like noise shielding member having a metal layer, is suppressed.

### BRIEF DESCRIPTION OF THE DRAWINGS

FIGS. 1A and 1B are respectively a perspective view and a cross-sectional view showing a communication cable according to a first embodiment of the present disclosure.

FIG. 2 is a perspective view showing a configuration of a film-like shield included in the communication cable according to the first embodiment.

FIGS. 3A and 3B are respectively a perspective view and a cross-sectional view showing a communication cable according to a second embodiment of the present disclosure.

FIG. 4 is a perspective view showing a configuration of a film-like shield included in the communication cable according to the second embodiment.

FIGS. 5A to 5C are side views showing configurations of communication cables used to evaluate shielding performance, in which the extension directions of slits formed in the film-like shields are different from each other. Slits are parallel to the axial direction of a core wire in Sample A shown in FIG. 5A, slits are diagonal (45 degrees) in Sample B shown in FIG. 5B, and slits are perpendicular in Sample C shown in FIG. 5C.

FIG. 6 is a diagram showing results obtained by evaluating shielding performance for four types of communication cable.

### DETAILED DESCRIPTION TO EXECUTE THE INVENTION

### Description of Embodiment of the Present Disclosure

First, embodiments of the present disclosure will be described.

A communication cable according to this disclosure includes: a core wire having a conductor and an insulating layer covering an outer circumference of the conductor; and a film-like shield that longitudinally surrounds an outer circumference of the core wire, in which the film-like shield includes a metal base layer constituted by a metal layer, and a linear or band-shaped stripe member that is in intimate contact with the metal base layer, and a plurality of the stripe members extend in an axial direction of the core wire and are spaced apart from each other in a circumferential direction of the core wire.

In the communication cable, the film-like shield disposed on the outer circumference of the core wire has the metal base layer, and thus functions as an electromagnetic wave shield and inhibits noise from entering the core wire and being emitted from the core wire. Because a plurality of the stripe members configured as linear or band-shaped members are in intimate contact with the surface of the metal base layer of the film-like shield and are provided in the circumferential direction of the core wire, a crack, which extends in a direction intersecting the axial direction of the core wire, is unlikely to form in the metal base layer of the film-like shield. Also, even when a crack is formed in a direction that intersects the axial direction, only a short crack will form. Because a crack that is long in a direction that intersects the axial direction is unlikely to form even when the communication cable is repeatedly bent, the communication cable can maintain high shielding performance even in an environment where the communication cable is subjected to bending, such as inside an automobile. Even if a crack is formed in the metal base layer of the film-like shield when the communication cable is bent, the crack is likely to extend in the axial direction of the core wire. Even if a crack extending in the axial direction is formed, the crack is less likely to lead to a significant deterioration of the shielding performance of the communication cable, compared to a crack extending in a direction that intersects the axial direction.

Here, it is preferable that the communication cable is configured as a coaxial cable, and further includes a braided shield that surrounds an outer side of the film-like shield and is constituted by a braided body of bare metal wires. Coaxial cables are susceptible to noise due to their structures. However, by providing the film-like shield on the outer circumference of the core wire, coaxial cables can have high shielding performance and high shielding performance can be maintained even when the cables are repeatedly bent. Furthermore, in particular, the shielding performance is increased by providing a braided shield, in addition to the film-like shield.

The stripe members are preferably made of a material containing an organic polymer. As a result, it is possible to easily form a film-like shield having stripe members using a lightweight and inexpensive material. Further, when a braided shield is disposed adjacent to the film-like shield, the metal base layer will be in contact with the braided shield via an organic polymer layer that forms the stripe members at locations where the stripe members are disposed. Therefore, the stripe member functions as a buffer, and when the communication cable is bent, a large load is not likely to be applied by the braided shield to a surface of the metal base layer, thus increasing the bending resistance of the communication cable.

In this case, the stripe members are preferably made of a material containing a conductive polymer. As a result, the entire surface of the film-like shield on which the metal base layer and the stripe members are disposed is conductive, thus realizing high shielding performance. Also, electrical conduction can be readily ensured between the film-like shield and a conductive member disposed overlapping the film-like shield, such as a braided shield.

Alternatively, the stripe members are preferably constituted by metal wires or conductive fibers. As a result, the stripe members have high material strength, thus increasing the mechanical strength of the film-like shield. Also, even when a crack is formed in the metal base layer, the conductive stripe member can function as a path along which a return current flows, and thus high shielding properties can be maintained.

It is preferable that the film-like shield further includes a metal coating layer as a metal layer that differs from the metal base layer, and the stripe members are held between the metal base layer and the metal coating layer. As a result, on the surface of the metal base layer, the state in which the stripe members extend in the axial direction of the core wire, and the state in which the stripe members are arranged at predetermined intervals can be maintained with ease. Also, in addition to the metal base layer, the metal coating layer also functions as a shield body and thus contributes to improving shielding performance.

It is preferable that the film-like shield further includes a sheet-like polymer base member containing an organic polymer, the metal base layer is formed on the surface of the polymer base member, and the stripe members are disposed on a surface of the metal base layer that is opposite to the polymer base member. The metal base layer can be easily formed as a thin metal film and stably maintained by using a polymer base member. Also, it is possible to increase the strength and handleability of the film-like shield overall.

In this case, it is preferable that the communication cable includes a braided shield that is constituted by a braided body of bare metal wires, and surrounds the outer circumference of the core wire, and a surface of the film-like shield that is opposite to a surface on which the polymer base member is disposed is in contact with the braided shield. It is possible to effectively increase shielding properties of the communication cable by disposing the braided shield, in addition to the film-like shield. In this case, electrical conduction can be ensured between the film-like shield and the braided shield by bringing, into contact with the braided shield, the surface of the film-like shield that is opposite to a surface on which the polymer base member is disposed, i.e., the surface of the film-like shield where the stripe members are disposed on the surface of the metal base layer, or a surface on which the metal coating layer is disposed.

### Details of Embodiment of the Present Disclosure

Hereinafter, a communication cable according to an embodiment of the present disclosure will be described in detail with reference to the drawings. Terms indicating the shape and arrangement of members, such as “parallel” and “perpendicular”, include not only geometrically strict concepts but also errors in a range that is generally allowable for communication cables. An angle includes an error of about ±10 degrees, for example.

### [1] Communication Cable According to First Embodiment

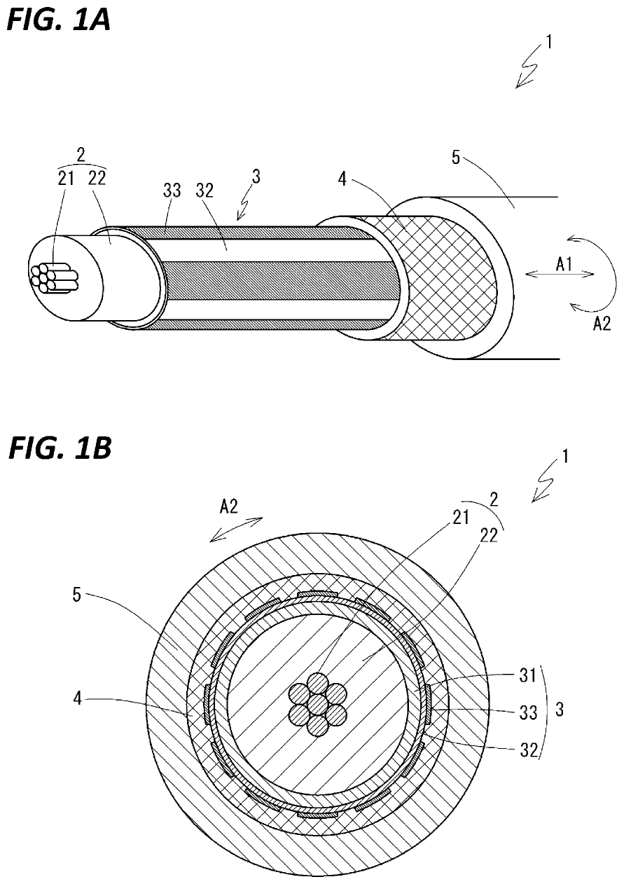

FIGS. 1A and 1B show a structure of a communication cable 1 according to a first embodiment of the present disclosure. FIG. 1A shows a perspective view of the communication cable 1, and FIG. 1B shows a cross-section of the communication cable 1 obtained by cutting the communication cable 1 perpendicularly to the axial direction thereof.

### (Overall Configuration of Communication Cable)

The communication cable 1 is configured as a coaxial cable. Specifically, the communication cable 1 includes a core wire 2 having a conductor 21 and an insulating layer 22 covering an outer circumference of the conductor 21. Also, a film-like shield 3 is provided on the outer circumference of the core wire 2. A braided shield 4 configured as a braided body obtained by braiding bare metal wires together is provided on the outer circumference of the film-like shield 3. Also, a sheath layer 5 is provided on an outer circumference of the braided shield 4.

The communication cable 1 configured as a coaxial cable having the film-like shield 3 and the braided shield 4 on the outer circumference of the core wire 2 can be favorably used to transmit signals with a high frequency of 1 GHz or more. However, the communication cable 1 according to the present disclosure is not limited to a communication cable having a structure described above as long as the film-like shield 3 surrounds the outer side of the core wire 2, and a configuration that corresponds to the communication frequency and applications need only be adopted. Although an insulated wire provided with the conductor 21 and the coating layer 22 is used alone as the core wire 2 in the above embodiment, a plurality of insulated wires may be used. Specifically, the core wire 2 can be configured to transmit differential signals by twisting two insulated wires together or arranging two insulated wires in parallel to each other. Also, if the influence of noise is not significant, the braided shield 4 may be omitted. Furthermore, although the layers described in the above embodiment are formed in direct contact with the outer circumference of an inner constituent layer, the communication cable 1 may include a constituent layer other than the layers described above as appropriate. Constituent members of the coaxial communication cable 1 mentioned above will be described below.

In the communication cable 1, the core wire 2 is a signal line for transmitting electrical signals, and includes a conductor 21 and an insulating layer 22 covering the outer circumference of the conductor 21. There is no particular limitation on materials that form the conductor 21 and the insulating layer 22. Although it is possible to use various metallic materials as a material forming the conductor 21, it is preferable to use copper or a copper alloy because of their high conductivity, for example. Although the conductor 21 may be configured as a single wire, the conductor 21 is preferably configured as a twisted wire obtained by twisting a plurality of bare wires (seven bare wires, for example), from the viewpoint of increasing the flexibility for when the communication cable 1 is bent. The insulating layer 22 insulates the conductor 21 in the core wire 2, and is made of a material containing an organic polymer. There is no particular limitation on the type of organic polymer, and examples thereof include olefin-based polymers such as polyolefin and olefin-based copolymers, halogen-based polymers such as polyvinyl chloride, various engineering plastics, elastomers, and rubber. The insulating layer 22 may contain an additive as appropriate, in addition to an organic polymer.

The film-like shield 3, which will be described later in detail, is configured as a composite body in which a polymer base member 31, a metal base layer 32, and a plurality of stripe members 33 arranged in rows are layered. The film-like shield 3 has the metal base layer 32 and thus functions as a noise shielding member. That is, the film-like shield 3 inhibits external electromagnetic waves from entering the core wire 2 and causing noise in signals transmitted through the core wire 2, and also inhibits electromagnetic waves generated by signals transmitted through the core wire 2 from being emitted to the outside and becoming a noise source.

The film-like shield 3 is longitudinally disposed on the outer circumference of the core wire 2. That is, the film-like shield 3 is disposed in the circumferential direction of the core wire 2, the surface of the film-like shield 3 surrounding the outer circumference of the core wire 2. By disposing the film-like shield 3 in a longitudinal arrangement, higher shielding performance can be achieved, compared to a laterally wound arrangement (a form in which the film-like shield, which is formed in the form of tape, is wound helically around the outer circumference of the core wire 2).

Although there is no particular limitation on the front and back directions when the film-like shield 3 is disposed on the outer circumference of the core wire 2, when the braided shield 4 is used in combination with the film-like shield 3, it is preferable that the film-like shield 3 is disposed such that a surface of the film-like shield that is opposite to a surface on which the polymer base member 31 is disposed is in contact with the braided shield 4. That is, a surface on which the stripe members 33 are disposed on the surface of the metal base layer 32 may be oriented toward the braided shield 4. In the embodiment shown in the drawings, the surface of the polymer base member 31 may be oriented inward and the surface where the stripe members 33 are disposed on the surface of the metal base layer 32 may be oriented outward. As a result, electrical conduction can be ensured between the metal base layer 32 and the braided shield 4 at exposed portions of the surface of the metal base layer 32 that are not covered by the stripe members 33.

The braided shield 4 is configured as a hollow tubular braided body formed by braiding a plurality of bare metal wires together. Examples of the bare metal wires forming the braided shield 4 include metallic materials such as copper, copper alloys, aluminum, or aluminum alloys, or wires obtained by plating, with tin or the like, a surface of these metallic materials. Although the braided shield 4 need not be provided in the communication cable 1, by providing the braided shield 4, the braided shield 4 functions as a noise shielding member, together with the metal base layer 32 of the film-like shield 3. The braided shield 4 may be provided on the outer side or the inner side of the film-like shield 3, but as shown in the drawings, it is preferable to provide the braided shield 4 on the outer side of the film-like shield 3, from the viewpoint of reducing signal loss, for example.

The sheath layer 5 is disposed as the outermost layer of the communication cable 1, and functions to protect the core wire 2, the film-like shield 3, and the braided shield 4 that are disposed on the inner side of the sheath layer 5. The sheath layer 5 is made of a material containing an organic polymer. There is no particular limitation on the type of organic polymer, and examples thereof include olefin-based polymers such as polyolefin and olefin-based copolymers, halogen-based polymers such as polyvinyl chloride, various engineering plastics, elastomers, and rubber. The sheath layer 5 may contain an additive as appropriate, in addition to an organic polymer. Furthermore, the sheath layer 5 may contain a powdery magnetic material, and in particular, a soft magnetic material. As a result, in the communication cable 1, the sheath layer 5 exhibits a noise shielding function together with the film-like shield 3 and the braided shield 4. Examples of the soft magnetic material include metal oxides such as ferrite, iron (pure iron or iron containing a small amount of carbon), and alloys such as various magnetic stainless steel and Fe—Ni-based alloys (permalloy).

### (Details of Film-Like Shield)

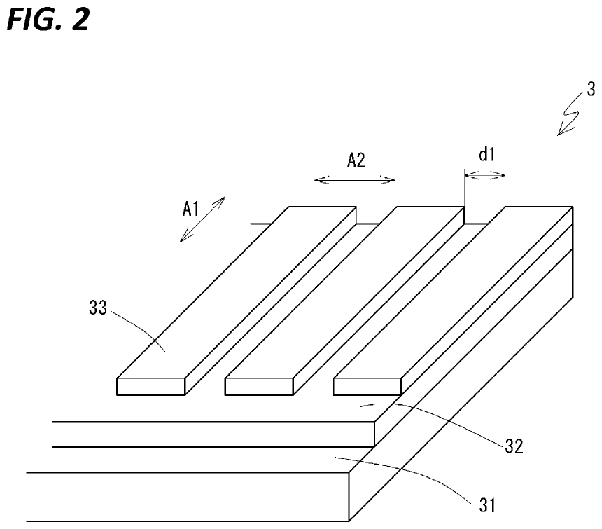

As shown in the overall diagram of the communication cable 1 shown in FIGS. 1A and 1B, and as shown in a perspective view of a structure of the film-like shield 3 in FIG. 2, the film-like shield 3 is configured as a composite body having a polymer base member 31, the metal base layer 32, and a plurality of stripe members 33 in rows layered in the stated order.

The polymer base member 31 is a sheet-like member made of a material containing an organic polymer. Although the polymer base member 31 need not be provided in the film-like shield 3, the metal base layer 32, which is a thin metal film, can be easily formed and stably held using the polymer base member 31. Also, it is possible to increase the mechanical strength and handleability of the film-like shield 3. There is no particular limitation on an organic polymer forming the polymer base member 31, and examples thereof include polyethylene terephthalate (PET) and polyolefins such as polypropylene (PP), and polyvinyl chloride (PVC). In particular, from the viewpoint of high mechanical strength and the like, PET can be favorably used. The polymer base member 31 may contain various additives as appropriate, in addition to an organic polymer.

The metal base layer 32 is configured as a continuous metal layer that covers one surface of the polymer base member 31, and functions as a shielding member that shields against electromagnetic noise in the communication cable 1. There is no particular limitation on the type of metal forming the metal base layer 32, and it is also possible to favorably use, in this embodiment, copper, a copper alloy, aluminum, an aluminum alloy, silver, a silver alloy, gold, a gold alloy, or the like, which are metals generally used as a shield material. In particular, it is preferable to use copper or a copper alloy. The metal base layer 32 may be formed by layering a plurality of metallic material layers. The metal base layer 32 is joined to the surface of the polymer base member 31 through vapor deposition, plating, adhesion, or the like, thus forming a single body.

Each stripe member 33 is configured as a linear member or band-shaped member. In the film-like shield 3, a plurality of stripe members 33 are disposed in intimate contact with the surface of the metal base layer 32, i.e., the surface of the metal base layer 32 opposite to a surface thereof that is in intimate contact with the polymer base member 31. The wording “each stripe member 33 is linear or band shaped” used in this specification indicates that the length in the width direction (direction A2) is shorter than the length in the longitudinal direction (direction A1). When the stripe member 33 is linear, the length in the thickness direction is the same as or longer than the length in the width direction, and when the stripe member 33 is band shaped, the length in the thickness direction is shorter than the length in the width direction. In the first embodiment, the stripe member 33 is particularly preferably a band shaped member.

There is no particular limitation on a material of the stripe member 33 as long as the stripe member 33 is configured as a linear member or band-shaped member, but the stripe member 33 preferably has bending resistance higher than that of the constituent material of the metal base layer 32. That is, it is preferable that the stripe member 33 is formed using a material that is less likely to cause impairments such as cracks and fractures when the communication cable 1 is bent, compared to the metal base layer 32.

In the communication cable 1 according to the first embodiment, the stripe members 33 are made of a material containing an organic polymer. Preferably, the stripe members 33 are formed using an organic polymer as a main component. There is no particular limitation on an organic polymer that forms the stripe members 33, and examples thereof include PET, polyolefins such as PP, thermoplastic resins such as PVC, and various curable resins. In particular, from the viewpoint of high mechanical strength and the like, PET can be favorably used. The stripe members 33 may contain various additives as appropriate, in addition to an organic polymer. Furthermore, it is preferable that the stripe members 33 are made of a material containing a conductive polymer, and have conductivity overall. In this case, the material that forms the stripe members 33 may contain an electrically conductive organic polymer, or the material may be one that has been imparted with electrical conductivity by mixing conductive additives into various organic polymers. The plurality of stripe members 33 may all be made of the same material, or a plurality of stripe members 33 made of different constituent materials may be exist together.

The stripe members 33 extend in the axial direction (the longitudinal direction in which the core wire 2 extends) A1 of the core wire 2 on the surface of the metal base layer 32. Also, the plurality of stripe members 33 are spaced apart from each other in a circumferential direction A2 of the core wire 2, i.e., in a direction orthogonal to the axial direction A1. The plurality of stripe members 33 are parallel to each other.

In the film-like shield 3, a plurality of stripe members 33 are disposed in the axial direction A1 of the core wire 2 on the surface of the metal base layer 32, and thus, a crack, which extends across a stripe member 33, is unlikely to form in the metal base layer 32. This is because the presence of the stripe members 33 prevents formation and growth of a cack. Therefore, a crack, which extends in a direction intersecting the axial direction A1 of the core wire 2, i.e., a direction A2 orthogonal or close to the axial direction A1, is unlikely to form in the metal base layer 32. Furthermore, even when a crack that extends in a direction intersecting the axial direction A1 is formed, the crack will be short in length.

If no stripe member 33 is formed on the surface of the metal base layer 32, a crack is likely to form in the metal base layer 32 at a bent portion when the communication cable is repeatedly bent. Because bending occurs along the axial direction A1 of the core wire 2, a bending and stretching force acting along the axial direction A1 is applied to the metal base layer 32, and thus, due to the application of the force, a crack is likely to form in a direction intersecting the axial direction A1. The crack formed in the metal base layer 32 reduces the shielding performance of the film-like shield 3. In particular, the more the crack extends in the direction A2 orthogonal to the axial direction A1, or in a direction closer thereto, the more the shielding performance deteriorates. This is because the path through which a return current flows in the axial direction A1 on the surface of the metal base layer 32 is cut off by the crack, and the return current flows around the crack, making it impossible to cancel out noise. In recent years, communication cables installed in automobiles need to have high noise shielding performance due to increasing frequencies. Communication cables disposed in doors or the like of automobiles are frequently subjected to loads that act to bend communication cables in the axial direction, which can lead to the formation of a crack that intersects the axial direction and can deteriorate the noise shielding properties.

In contrast, because the stripe members 33 are disposed on the metal base layer 32 of the film-like shield 3, even when the communication cable 1 according to this embodiment is repeatedly bent, cracks that extend across stripe members 33 in a direction intersecting the axial direction A1 are unlikely to form. Therefore, high shielding performance is maintained for a long period of time even in an environment in which the communication cable 1 is bent. Therefore, it is possible to favorably use the communication cable 1 according to this embodiment at the location where a load is applied in a bending direction, and high noise shielding properties are required, such as inside an automobile.

In the film-like shield 3, a crack that extends in the axial direction A1 of the core wire 2, i.e., a direction that is parallel to the axial direction A1, or a direction that is close to this, may form in the metal base layer 32 even when the stripe members 33 are provided. However, as will be described in later examples, a crack extending in the axial direction A1 will not deteriorate the shielding performance of the metal base layer 32 as much as cracks extending in a direction that intersects the axial direction A1. This is because cracks extending in the axial direction A1 do not greatly influence the path of the return current flowing through the metal base layer 32. As a result of a crack being formed in the metal base layer 32 when the communication cable 1 is repeatedly bent, it is possible to alleviate stress applied to the metal base layer 32. Therefore, when the communication cable 1 is bent, on the metal base layer 32 of the film-like shield 3, the presence of the stripe members 33 suppresses the formation of cracks extending in a direction that intersects the axial direction A1 in the metal base layer 32, and if a crack forms along the axial direction A1, mechanical stress associated with bending of the metal base layer 32 can be reduced as a result of stress relaxation, while avoiding a significant deterioration of shielding performance due to crack formation.

Further, because the stripe members 33 provided on the film-like shield 3 of the communication cable 1 according to this embodiment are made of a material containing an organic polymer, the bending resistance of the communication cable 1 can also be increased by reducing a load applied to the film-like shield 3 by adjacent members through bending, in addition to suppression of the deterioration of the shielding performance through bending. Specifically, when an organic polymer layer of the stripe members 33 is interposed between the metal base layer 32 and the braided shield 4, the stripe members 33 function as buffers. Specifically, the load applied to the metal base layer 32 by the braided shield 4 through contact with the braided shield 4 when the communication cable is bent, and warping of the metal base layer 32 caused by the applied load are alleviated by the stripe members 33 configured as an organic polymer layer interposed therebetween, and thus impairments such as excessive deformation and cracks are less likely to occur in the metal base layer 32 accompanying bending.

From the viewpoint of efficiently suppressing the formation of cracks that intersect the axial direction A1 in the film-like shield 3 by the stripe members 33, and from the viewpoint of obtaining the effects at any position in the circumferential direction A2, an arrangement interval d1 between stripe members 33 is preferably 1 mm or less in length, and 15% or less of the circumferential length (the length of a straight line extending around the surface of the metal base layer 32 once along the circumferential direction A2 of the core wire 2). The smaller the arrangement interval d1 between stripe members 33 is, the higher the crack suppression effect is. Therefore, there is no particular limitation on the arrangement interval d1 between stripe members 33. However, from the viewpoint of easily arranging stripe members 33 on the surface of the metal base layer 32, for example, the arrangement interval d1 is preferably 0.4 mm or more in length and 5% or more of the circumferential length, for example. The stripe members 33 do not need to be disposed at equal intervals along the circumferential direction A2. However, from the viewpoint of obtaining the same crack suppression effect at positions in the circumferential direction A2, the stripe members 33 are preferably disposed at equal intervals with an error of within about ±10%.

The coverage, which is the area of a region where the stripe members 33 are provided (the area of the region covered by the stripe members 33), of the area of the entire surface of the metal base layer 32, is preferably 40% or more, from the viewpoint of effectively suppressing the formation of a crack that intersects the axial direction A1. On the other hand, the coverage of the surface of the metal base layer 32 that is not covered by the stripe members 33 and is covered by the braided member 4 is preferably 80% or less, from the viewpoint of sufficiently ensuring electrical conduction with the braided shield 4. Note that, when the stripe members 33 contain a conductive polymer and exhibit conductivity overall, it is also possible to obtain electrical conduction between the stripe members 33 and the braided shield 4 at the location where the metal base layer is covered by the stripe members 33.

There is no particular limitation on a method for bringing the stripe members 33 that contain an organic polymer into intimate contact with the surface of the metal base layer 32, and adhesion is favorably used. In this case, when the constituent material of the stripe members 33 is made of thermoplastic resin or various curable resins that exhibit adhesiveness to the metal base layer 32, it is sufficient to form the stripe members 33 by disposing a liquid resin material in a predetermined stripe pattern on the surface of the metal base layer 32 and solidifying the resin material. On the other hand, when the constituent material of the stripe members 33 does not exhibit adhesiveness to the metal base layer 32, or when it is difficult to dispose a liquid constituent material on the surface of the metal base layer 32, for example, it is sufficient to adhere the stripe members 33 to the surface of the metal base layer 32 using an adhesive or a bonding agent, which is different from the constituent material of the stripe members 33. When the stripe members 33 contain a conductive polymer and exhibit conductivity overall, it is preferable to use a conductive adhesive or a conductive bonding agent. Note that, when the stripe members 33 are adhered to a surface of the metal base member 32 using an adhesive or a bonding agent, adjacent stripe members 33, which are disposed parallel to each other and spaced apart from each other at predetermined intervals, may be connected using intersecting members that are disposed to intersect a direction in which the stripe members 33 extend (the axial direction A1), in order to improve the handleability of the stripe members 33, for example. From the viewpoint of making it easier to allow the formation of cracks extending in the axial direction A1 on the surface of the metal base layer 32, and from the viewpoint of making it easier to ensure electrical conduction between the metal base layer 32 and the braided shield 4, for example, the area of the surface of the metal base layer 32 occupied by the intersecting members is preferably reduced to 20% or less of the area of the surface of the metal base layer 32 occupied by the stripe members 33.

Note that, from the viewpoint of structural simplicity and weight reduction, it is preferable that no other layer is provided on the surface, of the film-like shield 3 that constitutes the communication cable 1 according to the first embodiment, where the stripe members 33 are disposed on the surface of the metal base layer 32. However, similarly to a film-like shield 3′ that constitutes a communication cable 1′ according to a second embodiment of the present disclosure, which will be described next, a metal coating layer 35 may be provided on the surface of the metal base layer 32 on which the stripe members 33 are provided, such that the stripe members 33 are held between the metal base layer 32 and the metal coating layer 35.

### [2] Communication Cable According to Second Embodiment

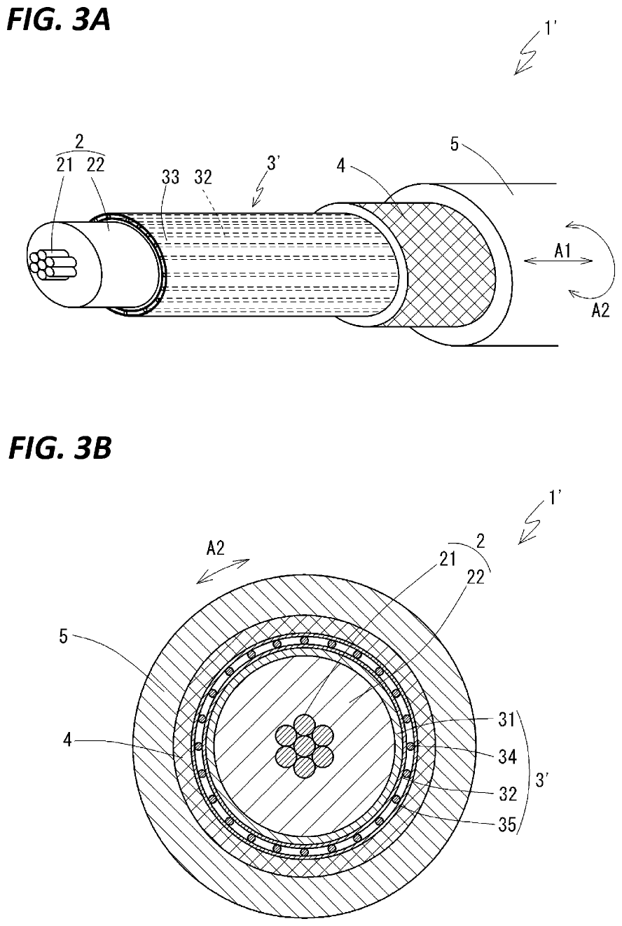

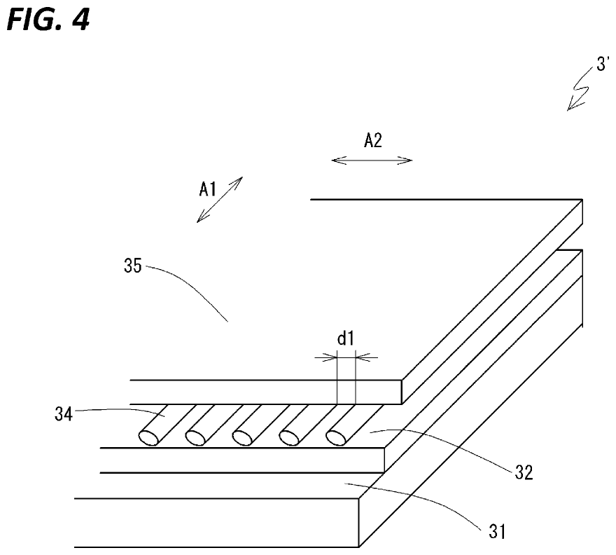

Next, a communication cable according to a second embodiment of the present disclosure will be described below. FIGS. 3A and 3B show a structure of the communication cable 1′ according to the second embodiment of the present disclosure. FIG. 3A is a perspective view of the communication cable 1′ and FIG. 3B is a cross-sectional view of the communication cable 1′ obtained by cutting the communication cable 1′ perpendicularly to the axial direction thereof. Also, FIG. 4 is a perspective view of a structure of a film-like shield 3′ included in the communication cable 1′ according to the second embodiment. Hereinafter, configurations common with the communication cable 1 according to the first embodiment are given the corresponding reference numerals in the drawings, and will not be described.

The communication cable 1′ according to the second embodiment has a configuration similar to that of the communication cable 1 according to the first embodiment, and includes a film-like shield 3′ having a configuration that differs from that of the first embodiment. The film-like shield 3′ of the communication cable 1′ according to the second embodiment is configured as a composite body in which a polymer base member 31, a metal base layer 32, stripe members 34, and a metal coating layer 35 are layered in the stated order. Although the polymer base member 31 and the metal coating layer 35 are possible constituent members, it is preferable that the communication cable 1′ includes the polymer base member 31 and the metal coating layer 35. When the communication cable 1′ includes the polymer base member 31, the film-like shield 3′ is disposed such that a surface of the film-like shield 3′ that is opposite to a surface on which the polymer base member 31 is disposed, i.e., a surface on which the stripe members 34 and the metal coating layer 35 are disposed, is in contact with the braided shield 4.

In the film-like shield 3′ in this second embodiment, it is possible to use the polymer base member 31 and the metal base layer 32 that are similar to those of the film-like shield 3 in the first embodiment, as the polymer base member 31 and the metal base layer 32. However, the stripe members 34 are configured as linear conductive members in this embodiment. More specifically, the stripe members 34 are constituted by metal wires or conductive fibers. There is no particular limitation on a specific constituent material of the stripe members 34. In the case of a metal wire, it is possible to favorably use a metallic material such as copper, a copper alloy, aluminum, or an aluminum alloy, or a wire obtained by plating, with tin, a surface of these metallic materials. The metal wire may be a single wire or a twisted wire, and a single wire is preferable from the viewpoint of ensuring a reduction in the diameter of the metal wire. On the other hand, when the stripe members 34 are constituted by conductive fibers, there is no particular limitation on the composition of the stripe members 34 as long as the stripe members 34 are flexible wire members other than a metal wire. Examples thereof include fibers obtained by mixing a metal and conductive substance powder such as a carbon material into an organic polymer to form fibers, and fibers obtained by providing a metal layer on the outer circumference of the organic polymer fibers.

The metal coating layer 35 is configured as a continuous metal layer, and functions to bring the stripe members 34 into intimate contact with the metal base layer 32. Also, the metal coating layer 35 also functions as a noise shielding member, together with the metal base layer 32. Similarly to the metal base layer 32, it is possible to favorably use, as a material that forms the metal coating layer 35, copper, a copper alloy, aluminum, an aluminum alloy, silver, a silver alloy, gold, and a gold alloy. In particular, it is preferable to use copper or a copper alloy. Although, similarly to the metal base layer 32, the metal coating layer 35 may also be combined with a base member made of an organic polymer. However, if the braided shield 4 is provided on the outer circumference of the film-like shield 3′, the metal coating layer 35 is preferably configured as a metal foil, which is independent and is not a composite with the base member, from the viewpoint of ensuring electrical conduction between the metal coating layer 35 and the braided shield 4.

Because the linear stripe members 34 are held between the metal base layer 32 and the metal coating layer 35 in the film-like shield 3′, the linear stripe members 34 are in intimate contact with the metal base layer 32. The stripe members 34 may be adhered to the surface of the metal base layer 32 via an adhesive or a bonding agent, in addition to or instead of the stripe members 34 being held by the metal coating layer 35. In this case, it is preferable that the adhesive or bonding agent has conductivity. Also, the stripe members 34 may be adhered to the metal coating layer 35, in addition to the metal base layer 32. The metal base layer 32 and the metal coating layer 35 may be bonded to each other at locations where the stripe members 34 are not disposed.

Similarly to the first embodiment, because a plurality of stripe members 34 are disposed in the axial direction A1 of the core wire 2 in the film-like shield 3′ in this embodiment, even if the communication cable 1′ is bent, the formation of cracks that intersect the axial direction A1 in the surface of the metal base layer 32 is suppressed, and even when a crack that extends in a direction intersecting the axial direction A1 is formed, the crack will be short in length. As a result, high shielding performance is maintained even when the communication cable 1′ is repeatedly bent. Also, even if a crack is formed in the metal base layer 32 due to the influence of bending or the like, the stripe members 34 function as the path of the return current because the stripe members 34 are made of a conductive material. Thus, the shielding performance of the film-like shield 3′ overall can be maintained. Furthermore, because the stripe members 34 have high material strength, the stripe members 34 also function as reinforcement members, and function to increase the mechanical strength of the film-like shield 3′. In particular, when the stripe members 34 are constituted by metal wires, the stripe members 34 can effectively function as return paths and function as reinforcement members.

From a similar viewpoint to the first embodiment, in this embodiment, the arrangement interval d1 between stripe members 34 in the film-like shield 3′ is preferably 1 mm or less in length, and 15% or less of the circumferential length. On the other hand, there is no particular limitation on the lower limit of the arrangement interval d1 of the stripe members 34, and the arrangement interval d1 is preferably 0.4 mm or more in length and 5% or more of the circumferential length, for example. The stripe members 34 do not need to be disposed at equal intervals along the circumferential direction A2. However, the stripe members 34 are preferably disposed at equal intervals with an error of within about ±10%. Also, from the viewpoint of obtaining a sufficient crack suppression effect and a function as a reinforcement member, each stripe member 34 has a diameter of 0.1 mm or more. On the other hand, from the viewpoint of ensuring sufficient flexibility, each stripe member 34 has a diameter of 0.6 mm or less. Further, in this embodiment, adjacent stripe members 34, which are disposed parallel to each other and spaced apart from each other at predetermined intervals, may also be connected using intersecting members. However, the area of the surface of the metal base layer 32 occupied by the intersecting members is preferably reduced to 20% or less of the area of the surface of the metal base layer 32 occupied by the stripe members 34.

### EXAMPLES

Examples will be described below. Note that the present invention is not limited to these examples. Here, a relationship between a direction in which a crack is formed in the metal base layer of the film-like shield and the influence of the crack on the shielding performance was examined.

### Production of Samples

Four types of coaxial communication cables were prepared as Samples A to D. As for all of the four types, a film-like shield, a braided shield, and a sheath layer were disposed in the stated order on an outer circumference of a core wire obtained by covering the outer circumference of a conductor (cross-sectional area of the conductor: 0.61 mm²) with an insulating layer. A copper metal base layer (thickness: 9 μm) bonded to one surface of a PET base member (thickness: 12 μm) as a single body was used as a film-like shield, and was disposed on the outer circumference of the core wire with a surface of the metal base layer facing outward.

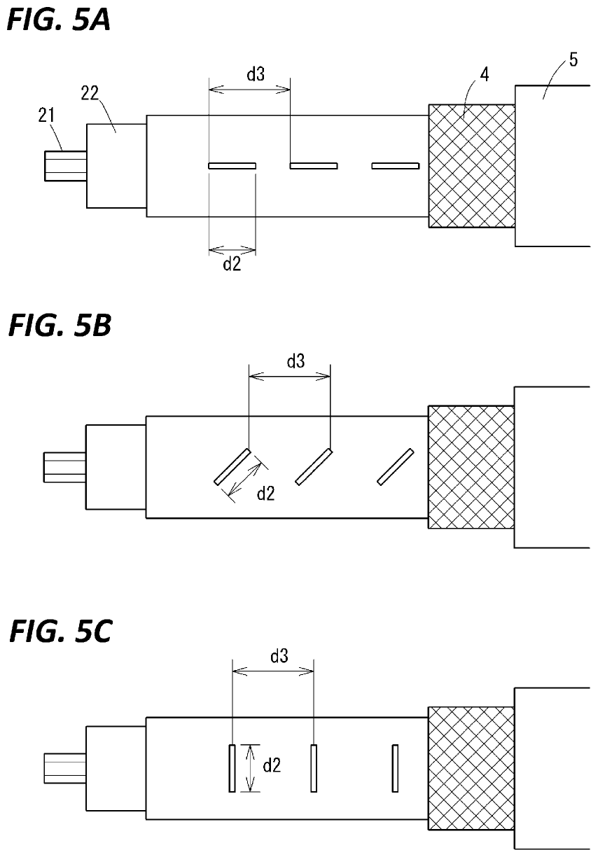

The communication cables of Samples A to D differed from each other in the presence or absence of slits in the film-like shield and the arrangement angle. As shown in FIGS. 5A to 5C, in Samples A to C, slits were formed in the surface of the metal base layer of the film-like shield, as models of cracks. In all of the samples, the slits were formed as openings extending through the metal base layer and the PET base member in the thickness direction. The length of a slit (d2 in the drawings) was 1 mm, and the width of a slit was the smallest processable value. Samples A to C differed from each other in the arrangement angle of the slits. The slits in Sample A were arranged parallel to the axial direction of the core wire, the slits in Sample B were arranged diagonally at an angle of 45 degrees to the axial direction of the core wire, and the slits in Sample C were arranged perpendicularly to the axial direction of the core wire. In all of the samples, the interval between slits (d3 in the drawings) was 2 mm. Sample D was used as a reference without slits formed in the film-like shield.

### (Test Method)

Each communication cable of Samples A to D was cut to a length of 1200 mm, and the shielding attenuation was measured in a region up to 3 GHz. Measurement was performed using a test method based on IEC 62153-4-4.

### (Test Results)

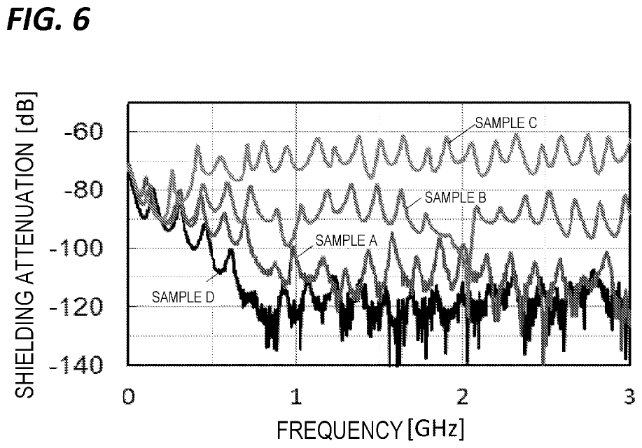

FIG. 6 shows the results obtained by measuring the shielding attenuation for Samples A to D. The measurement frequency is shown on the horizontal axis, and the shielding attenuation (units: dB) is shown on the vertical axis, indicating that the lower the measured value at a frequency is on the vertical axis, the higher the obtained shielding performance is.

As shown in FIG. 6, Sample D, which had no slits in the film-like shield, had the highest shielding performance. In Sample A in which slits were formed parallel to the axial direction of the core wire, the shielding performance deteriorated, compared to Sample D in which no slits were formed, but the deterioration amount was negligible. In particular, the shielding attenuation of Sample A was almost the same as that of Sample D in the region of a frequency of about 2 GHz or higher. In contrast, Samples B and C, in which slits were formed at an angle to the axial direction, had significantly lower shielding performance than Sample D. In particular, the shielding performance of Sample C, in which slits were formed perpendicularly to the axial direction, significantly deteriorated.

As described above, it was found that, when slits are formed in a metal base layer of a film-like shield disposed in a communication cable, the closer the direction in which the slits extend to a direction perpendicular to the axial direction of a core wire, the greater the deterioration of shielding performance. When the direction in which the slits extend is parallel to the axial direction, even when slits are formed, the influence of the slits on shielding performance will be minimized. In particular, in a high frequency region, the influence of the slits on shielding performance is reduced, and high shielding performance is maintained even when slits are formed.

The present invention is not limited to the above embodiments, and various modifications can be made without departing from the spirit of the present invention.

### LIST OF REFERENCE NUMERALS

1,1′ Communication cable
2 Core wire
21 Conductor
22 Insulating layer
3,3′ Film-like shield
31 Polymer base member
32 Metal base layer
33, 34 Stripe member
35 Metal coating layer
4 Braided shield
5 Sheath layer
A1 Axial direction of core wire
A2 Circumferential direction of core wire
d1 Arrangement interval between stripe members
d2 Length of slit
d3 Interval between slits

1. A communication cable comprising:
a core wire having a conductor and an insulating layer covering an outer circumference of the conductor; and
a film-like shield that longitudinally surrounds an outer circumference of the core wire,
wherein the film-like shield includes
a metal base layer constituted by a metal layer, and
a linear or band-shaped stripe member that is made of a material containing an organic polymer selected from polyethylene terephthalate, a polyolefin, and polyvinyl chloride, or a substance imparted with electrical conductivity by mixing a conductive additive into the organic polymer,
a plurality of the stripe members extend in an axial direction of the core wire and are spaced apart from each other in a circumferential direction of the core wire, and
a constituent material of the stripe members does not exhibit adhesiveness to the metal base layer, and the stripe members are adhered to a surface of the metal base layer using an adhesive or a bonding agent that is different from the constituent material of the stripe members.

2. The communication cable according to claim 1,
wherein the stripe members are made of a material containing a substance imparted with electrical conductivity by mixing a conductive additive into the organic polymer.

3. The communication cable according to claim 1,
wherein the stripe members are made of a material containing polyethylene terephthalate.

4. The communication cable according to claim 1,
wherein the film-like shield further includes a metal coating layer as a metal layer that differs from the metal base layer, and
the stripe members are held between the metal base layer and the metal coating layer.

5. The communication cable according to claim 1,
wherein no other layer is provided on a surface of the film-like shield where the stripe members are disposed on a surface of the metal base layer.

6. The communication cable according to claim 1,
wherein the communication cable is configured as a coaxial cable, and
further includes a braided shield that surrounds an outer side of the film-like shield and is constituted by a braided body of bare metal wires.

7. The communication cable according to claim 1,
wherein the film-like shield further includes a sheet-like polymer base member containing an organic polymer,
the metal base layer is formed on a surface of the polymer base member, and
the stripe members are disposed on a surface of the metal base layer that is opposite to the polymer base member.

8. The communication cable according to claim 7,
wherein the communication cable includes a braided shield that is constituted by a braided body of bare metal wires, and surrounds the outer circumference of the core wire, and
a surface of the film-like shield that is opposite to a surface on which the polymer base member is disposed is in contact with the braided shield.

9. The communication cable according to claim 1,
wherein an arrangement interval between stripe members in the film-like shield is 1 mm or less.

10. (canceled)
